(19) United States
(12) Patent Application Publication
(10) Pub. No.: US 2026/0223674 A1
(43) Pub. Date: Jul. 30, 2026

(54) METHODS FOR FABRICATING OF A SUBSTRATE WITH GRAPHITE EMBEDDED CUSTOMIZED HEAT SPREADING

(71) Applicant: Toyota Motor Engineering & Manufacturing North America, Inc., Plano, TX (US)

(72) Inventors: Feng Zhou, Ann Arbor, MI (US); Tianzhu Fan, Houston, TX (US); Ercan M. Dede, Ann Arbor, MI (US); Shailesh N. Joshi, Ann Arbor, MI (US)

(73) Assignee: Toyota Motor Engineering & Manufacturing North America, Inc., Plano, TX (US)

(21) Appl. No.: 19/041,403

(22) Filed: Jan. 30, 2025

(51) Int. Cl. H01L 23/373

(52) U.S. Cl. CPC H10W 40/258

(57) ABSTRACT

Embodiments herein are direct to a method for fabricating a substrate with graphite embedded for customized heat spreading that includes bonding a plurality of graphite members having a planar orientation into a single-layer plate arrangement, the plurality of graphite members are arranged such that one of the plurality of graphite members has a high thermal conductivity in a lateral direction and a low thermal conductivity in a longitudinal direction and at least two of the plurality of graphite members each have a high thermal conductivity in the longitudinal direction and a low thermal conductivity in the lateral direction, bonding the single layer plate arrangement into a recess, and positioning a cover member in a closed state to enclose the single layer plate arrangement.

### TECHNICAL FIELD

The present specification generally relates to heat dissipation generated by power electronic assemblies and, more specifically, to methods for fabricating copper-graphite composite substrates.

### BACKGROUND

Due to the increased use of electronics in vehicles, there is a need to make electronic systems more compact. One component of these electronic systems is a power electronic device used as a switch. Power electronic devices have large cooling requirements due to the heat generated. It is generally known for heat spreader assemblies to include power electronic devices bonded into a pocket of on a copper-graphite composite substrate. The size of the copper-graphite composite substrate could be optimized based on the size of the power electronic devices. In these examples, the interior of the substrate is a single-layer anisotropic graphite. It is also known for a metal substrate to be processed with a cave or well and then the graphite is added into the cave and then covered with a top lid. The heat spreader is then bonded together and machined with several caves on the top surface for the positioning of the power electronic devices.

However, these known heat spreaders contain only one piece of graphite and thus the movement of heat is not customizable.

### SUMMARY

In one embodiment, a method for fabricating a substrate with graphite embedded for customized heat spreading directions is provided. The method includes bonding a plurality of graphite members having a planar orientation into a single-layer plate arrangement, the plurality of graphite members are arranged such that one of the plurality of graphite members has a high thermal conductivity in a lateral direction and a low thermal conductivity in a longitudinal direction and at least two of the plurality of graphite members each have a high thermal conductivity in the longitudinal direction and a low thermal conductivity in the lateral direction, bonding the single layer plate arrangement into a recess, and positioning a cover member in a closed state to enclose the single layer plate arrangement.

In another embodiment, a method for fabricating a substrate with graphite embedded for customized heat spreading directions is provided. The method includes bonding a plurality of graphite members to form a single-layer plate arrangement, the plurality of graphite members are arranged such that one of the plurality of graphite members has a high thermal conductivity in a first direction and a low thermal conductivity in a second direction, the second direction different from the first direction and at least two of the plurality of graphite members each have the high thermal conductivity in the first direction and the low thermal conductivity in the second direction, slicing the single-layer plate arrangement into a plurality of graphite elongated members, dividing the plurality of graphite elongated members into a plurality of graphite insert members, and bonding the plurality of graphite insert members into a corresponding one of a plurality of recesses of the substrate.

In yet another embodiment, a method for fabricating a substrate with graphite embedded for customized heat spreading directions is provided. The method includes bonding a plurality of graphite members into single-layer plate arrangement, the plurality of graphite members are arranged such that one of the plurality of graphite members has a high thermal conductivity in a first direction and a low thermal conductivity in a second direction, the second direction different from the first direction and at least two of the plurality of graphite members each have the high thermal conductivity in the first direction and the low thermal conductivity in the second direction, slicing the single-layer plate arrangement into a plurality of graphite elongated members, adding the plurality of graphite elongated members into a recess, and positioning a cover member to enclose the plurality of graphite elongated members.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1A schematically depicts a perspective view of an example heat spreader assembly, according to one or more embodiments described and illustrated herein;

FIG. 1B schematically depicts a cross-section view of the example heat spreader assembly taken from line 1B-1B of FIG. 1A, according to one or more embodiments described and illustrated herein;

FIG. 2 schematically depicts a top plan view of the example heat spreader assembly FIG. 1A depicting an example method of fabricating a recess within a substrate, according to one or more embodiments described and illustrated herein;

FIG. 3A schematically depicts a first example method of joining a plurality of sectional graphite members into a single-layer graphite plate of FIG. 1B into a side-center-side graphite configuration and sliced into a plurality of elongated members according to one or more embodiments described and illustrated herein;

FIG. 3B schematically depicts a second example method of joining a plurality of sectional graphite members into a single-layer graphite plate of FIG. 1B into a side-center-side graphite configuration according to one or more embodiments described and illustrated herein;

FIG. 3C schematically depicts a third example method of joining a plurality of sectional graphite members into a single-layer graphite plate of FIG. 1B into four portion graphite configuration according to one or more embodiments described and illustrated herein;

FIG. 4A schematically depicts a perspective view of the example heat spreader assembly FIG. 1A depicting an example method of adding the single-layer graphite plate of FIG. 3B into the recess of the example heat spreader assembly FIG. 1A and adding a cover member according to one or more embodiments described and illustrated herein;

FIG. 4B schematically depicts a perspective view of the example heat spreader assembly FIG. 1A depicting an example method of adding the single-layer graphite plate of FIG. 3C into the recess of the example heat spreader assembly FIG. 1A and adding a cover member according to one or more embodiments described and illustrated herein;

FIG. 5A schematically depicts a perspective view of the example heat spreader assembly FIG. 4A depicting an example method of enclosing the recess with the cover member and baking the substrate to form the example heat spreader assembly FIG. 1A according to one or more embodiments described and illustrated herein;

FIG. 5B schematically depicts a perspective view of the example heat spreader assembly FIG. 4B depicting an example method of enclosing the recess with the cover member and baking the substrate to form the example heat spreader assembly FIG. 1A according to one or more embodiments described and illustrated herein;

FIG. 5C schematically depicts a top plan view of the example heat spreader assembly FIG. 4B depicting an example method of sintering the cover member to the substrate, and baking the substrate to form the example heat spreader assembly FIG. 1A according to one or more embodiments described and illustrated herein;

FIG. 6A schematically depicts a top plan view of the side-center-side graphite configuration of FIG. 3B according to one or more embodiments described and illustrated herein;

FIG. 6B schematically depicts a color map of the side-center-side graphite configuration of FIG. 6A illustrating heat movement along a high thermal conductivity direction according to one or more embodiments described and illustrated herein;

FIG. 7 graphically depicts an influence of a height of the center graphite member of side-center-side graphite configuration of FIG. 6A, according to one or more embodiments described and illustrated herein;

FIG. 8A schematically depicts a top plan view of the four portion graphite configuration of FIG. 3C according to one or more embodiments described and illustrated herein;

FIG. 8B schematically depicts a color map of the four portion graphite configuration of FIG. 8A illustrating heat movement along a high thermal conductivity direction according to one or more embodiments described and illustrated herein;

FIG. 9A schematically depicts a top plan view of a second aspect of the four portion graphite configuration of FIG. 3C according to one or more embodiments described and illustrated herein;

FIG. 9B schematically depicts a color map of the second aspect of the four portion graphite configuration of FIG. 9A illustrating heat movement along a high thermal conductivity direction according to one or more embodiments described and illustrated herein;

FIG. 10A schematically depicts a top plan view of the example heat spreader assembly FIG. 1A depicting an example method of fabricating a plurality of recesses within a substrate, according to one or more embodiments described and illustrated herein;

FIG. 10B schematically depicts an example method of further dividing the plurality of elongated members of FIG. 3A into a plurality of inset members and bonding the plurality of inset members into corresponding one of the plurality of recesses according to one or more embodiments described and illustrated herein;

FIG. 10C schematically depicts a top plan view of the example heat spreader assembly FIG. 10B depicting an example method of sintering the cover member to the substrate, ; according to one or more embodiments described and illustrated herein

FIG. 10D schematically depicts a top plan view of the example heat spreader assembly FIG. 10C depicting an example method of closing the cover member into a closed state and baking the substrate to form the example heat spreader assembly FIG. 1A according to one or more embodiments described and illustrated herein;

FIG. 11 schematically depicts a top plan view of the example heat spreader assembly FIG. 10D with the cover member in an access state and depicting an example arrangement of the plurality of inset members and power electronic devices according to one or more embodiments described and illustrated herein.

### DETAILED DESCRIPTION

Embodiments described herein are generally directed to methods for heat spreaders, and more particular to methods for fabricating a substrate with graphite embedded for customized heat spreading directions. The methods described herein utilize a substrate with sectional graphite members that are embedded and orientated for customized heat spreading directions. The sectional graphite members provide for customization in terms of sizes, shapes, configurations, and orientations to optimize heat transfer based on the type of heat source, location of heat source, contact size of the hear source, and desirable locations to push or otherwise direct the heat. This enables robust control and flexibility in designing heat spreader assemblies while providing customized and improved thermal conductivity. As such, the substrates described herein improve the heat flux from the heat spreader to the cooling device, thereby increasing heat spreading and cooling performance to decrease a power electronic device's temperature considerably in a way that is tunable and customized for moving the heat into desirable areas compared to conventional heat spreader assemblies.

The method described herein for fabricating the substrate with sectional graphite members embedded for customized heat spreading directions includes bonding a plurality of graphite members, the plurality of graphite members are arranged or orientated such that one of the plurality of graphite members has a high thermal conductivity in a lateral direction and a low thermal conductivity in a longitudinal direction and at least two of the plurality of graphite members each have a high thermal conductivity in the longitudinal direction and a low thermal conductivity in the lateral direction, slicing the plate into a plurality of graphite elongated members, adding the plurality of graphite elongated members into a recess, and sintering a cover member to movably enclose the plurality of graphite elongated members. In some embodiments, the plurality of graphite members are arranged in a side-center-side graphite member configuration such that a center graphite member and two side graphite members of the plurality of graphite members contact with the center graphite member along two parallel edges of the center graphite member to define a plate arrangement. The center graphite member has the high thermal conductivity (high k) in the lateral direction (i.e., in the +/−X direction) and the low thermal conductivity (low k) in the longitudinal direction (i.e., in the +/−Y direction). The two side graphite members each have a high thermal conductivity (high k) in the longitudinal direction (i.e., in the +/−Y direction) and the low thermal conductivity (low k) in the lateral direction (i.e., in the +/−X direction).

In another embodiment, the plurality of graphite members are arranged in a first portion, a second portion, a third portion and a fourth portion to define a plate arrangement having a center point, an apex of each of the first portion, the second portion, the third portion and the fourth portion contacting the center point. In this arrangement, the first portion and the third portion each have the high thermal conductivity in the longitudinal direction and the low thermal conductivity in the lateral direction and the second portion and the fourth portion each have the high thermal conductivity in the lateral direction and the low thermal conductivity in the longitudinal direction. The first portion, the second portion, the third portion and the fourth portion each have the high thermal conductivity in a vertical direction.

In another embodiment, the method further includes dividing the plurality of graphite elongated members into a plurality of graphite insert members following the step of slicing the plate into a plurality of graphite elongated members, then adding the plurality of graphite insert members into a corresponding one of a plurality of copper recess and sintering a copper lid to movably enclose the plurality of graphite insert members. In this arrangement, a density and the high thermal conductivity of each of the plurality of graphite insert members is configured to be tuned to guide a heat from a heat source to a desirable location. The high thermal conductivity of each of the plurality of graphite insert members tuned to the first direction is configured to guide the heat from the heat source to the desirable location and push the heat away from an undesirable location to generate a low heat spreading area for other devices. The high thermal conductivity of each of the plurality of graphite insert members tuned to the first direction is further configured to eliminate heat interference between the heat source and the other devices. Each of the plurality of graphite pieces has a high thermal conductivity in a third direction, the third direction being perpendicular to a substrate surface of each of plurality of graphite pieces.

As described in more detail below, the heat spreaders of the present disclosure provide enhanced thermal properties due to graphite layers that promote heat flux flow toward a cooling device, such as a heat sink or a cold plate. The heat spreaders described herein a single-layer graphite layer plate in a compact package. The graphite has a varying direction of high thermal conductivity, making it useful to conduct heat flux toward the cooling device. However, graphite does not have an isothermal profile. Rather, graphite has an anisothermal profile with high conductivity along two axes and low thermal conductivity in a third axis. To account for the anisothermal profile of graphite, the disclosed single-layer graphite layer plate may have three or more adjacent graphite pieces having high thermal conductivity along a thickness direction to balance heat spreading capabilities across three axes of the graphite. Particularly, each graphite piece has a high thermal conductivity across two axes that differs from the two axes of another adjacent graphite piece to provide a balanced thermal conductivity along each of the three axes of the single-layer graphite layer plate. The disclosed single-layer graphite layer plate includes customizable graphite pieces in terms of sizes and configurations to optimize heat transfer based on the heat source's location and contact size, and the single-layer graphite layer's shape. This enables robust control and flexibility in heat transfer. Further, the heat spreaders described herein may include bonding materials. The bonding materials described herein for bonding the heat spreaders are particularly adapted for increased thermal conductivity relative to other bonding technologies, while also maintaining an ability to electrically insulate the heat spreaders. The methods disclosed herein provide for improved heat flux movement from the heat spreader to the cooling device, thereby increasing heat spreading and cooling performance.

As used herein, a “power electronics device” means any electrical component used to convert DC electrical power to AC electrical power and vice-versa. Embodiments may also be employed in AC-AC converter and DC-DC converter applications. Non-limiting examples of power electronics devices include power metal-oxide-semiconductor field effect transistors (MOSFET), insulated-gate bipolar transistors (IGBT), thyristors, and power transistors.

Various embodiments of method for fabricating heat spreader assemblies are described in detail below. Whenever possible, the same reference numerals will be used throughout the drawings to refer to the same or like parts.

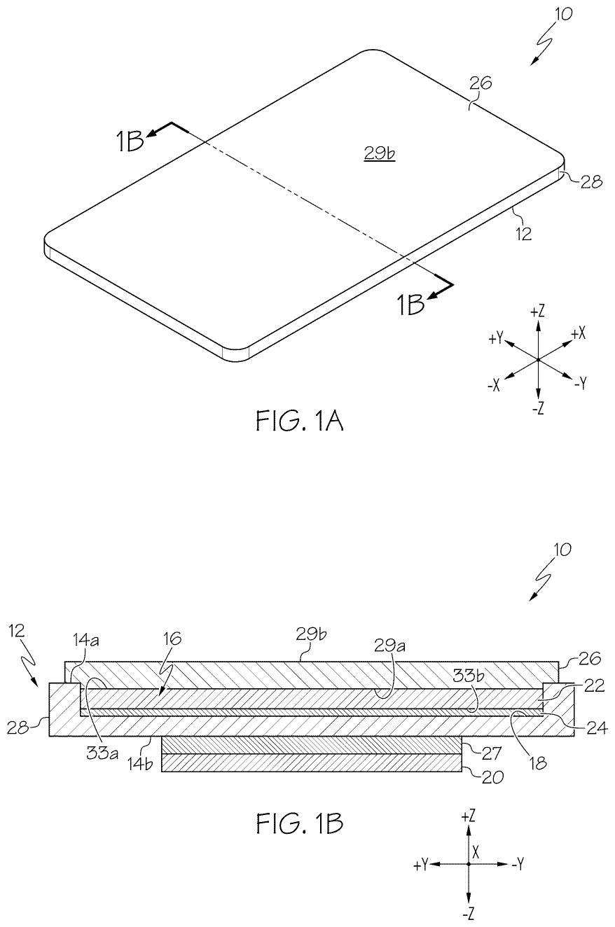

FIG. 1A depicts an example copper-graphite composite substrate. An axial length of the copper-graphite composite substrate is indicated by the term “longitudinal direction” which refers to the forward-rearward direction of the assembly (i.e., in the +/−Y direction depicted in FIG. 1A). The width of the copper-graphite composite substrate is indicated by the term “lateral direction” which refers to the cross direction (i.e., in the +/−X direction depicted in FIG. 1A), and is transverse to the longitudinal direction. The height of the copper-graphite composite substrate is indicated by the term “vertical direction” which refers to the upward-downward direction of the assembly (i.e., in the +/−Z direction depicted in FIG. 1A).

Referring to FIGS. 1A and 1B, a heat spreader assembly 10 is schematically depicted. The heat spreader assembly 10 includes a substrate 12 that has an inner surface 14a and an opposite outer surface 14b to define a thickness there between. The substrate 12 further includes recess 16 or receiving cavity extending from the inner surface 14a in the vertical direction (i.e., in the-Z direction) of the substrate 12 towards the outer surface 14b of the substrate 12 through a portion of a thickness of the substrate 12 to define a recess interior surface 18. The recess interior surface 18 is positioned closer in distance to the outer surface 14b (e.g., less of a thickness between the surfaces) than the inner surface 14a is positioned closer to the outer surface 14b (e.g., greater thickness between the surfaces) in the vertical direction (i.e., in the +/−Z direction).

At least one power electronic device 20 is coupled to the outer surface 14b of the substrate 12. In some embodiments, the at least one power device 20 may be coupled to the outer surface 14b via a bonding layer 27 via a plurality of bonding techniques, such as silver sintering, soldering, copper sintering, and the like. Other techniques such as die bonding, wire bonding, flip chip bonding, soldering, epoxy, combinations thereof, and/or the like may be used. Further, other coupling techniques may be utilized as appreciated by those skilled in the art.

A plurality of graphite members 22 are bonded together to define a plate that has an interior surface 33a and an opposite exterior surface 33b to define a thickness there between. The plate defined by the plurality of graphite members 22 is embedded within recess 16 and may be bonded to the recess interior surface 18 via the exterior surface 33b facing or abutting with the recess interior surface 18. The plurality of graphite members 22 may be bonded to the recess interior surface 18 via a bonding layer 24. The bonding layer 24 between the plurality of graphite members 22 and the recess interior surface 18 may be via active metal brazing. In other embodiments, the bonding layer 24 may be formed from a solder layer, for example. As another example, the bonding layer 24 may be a transient liquid phase bonding layer.

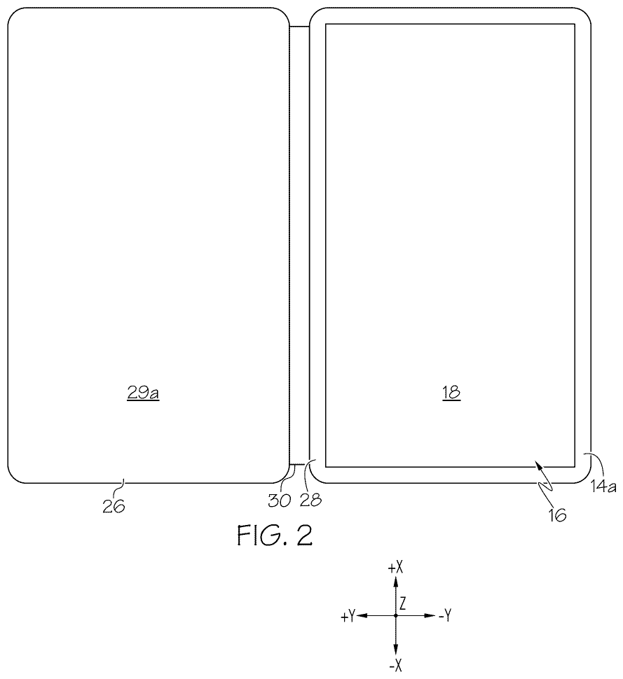

Referring now to FIGS. 2-5C and 10A-10D, example method steps for fabricating a heat spreader assembly 10 that includes the substrate 12 with the plurality of graphite members 22 embedded for customized heat spreading directions are schematically depicted. It should be understood that the steps described herein and associate with FIGS. 2-5C and 10A-10D will be described as being separate tasks, in other embodiments, the various separate tasks may be combined or omitted. Further, while the separate tasks associated with FIGS. 2-5C and 10A-10D will described as being performed in a particular order, in other embodiments, the separate tasks associated with FIGS. 2-5C and 10A-10D may be performed in a different order.

The method for fabricating a heat spreading includes fabricating the substrate 12, as best depicted in FIG. 2, as a solid substrate that includes the inner surface 14a spaced apart from the outer surface 14b to define the thickness. That is, the substrate 12 may be a monolithic structure rather than including a plurality of various metal layers. The recess 16 or receiving cavity is fabricated into the substrate 12 and may be formed by chemical etching, stamping, and/or machined, for example, or any other suitable process. It should be appreciated that each substrate 12 may be formed individually or a plurality of substrates 12 may be formed into a single sheet, which is later sliced into individual substrates, as appreciated by those having skill in the art.

In the depicted embodiment of FIG. 2, the recess 16 may be a single recess that is generally rectangular in shape such that its length dimension in the lateral direction (i.e., in the +/−X direction) is greater than its width dimension in the longitudinal direction (i.e., in the +/−Y direction). This is non-limiting, and the recess 16 may be any shape, including without limitation, square, elliptical, circular hexagonal, octagonal, and/or the like. The recess 16 is configured to receive a layer of graphite, as discussed in greater detail herein.

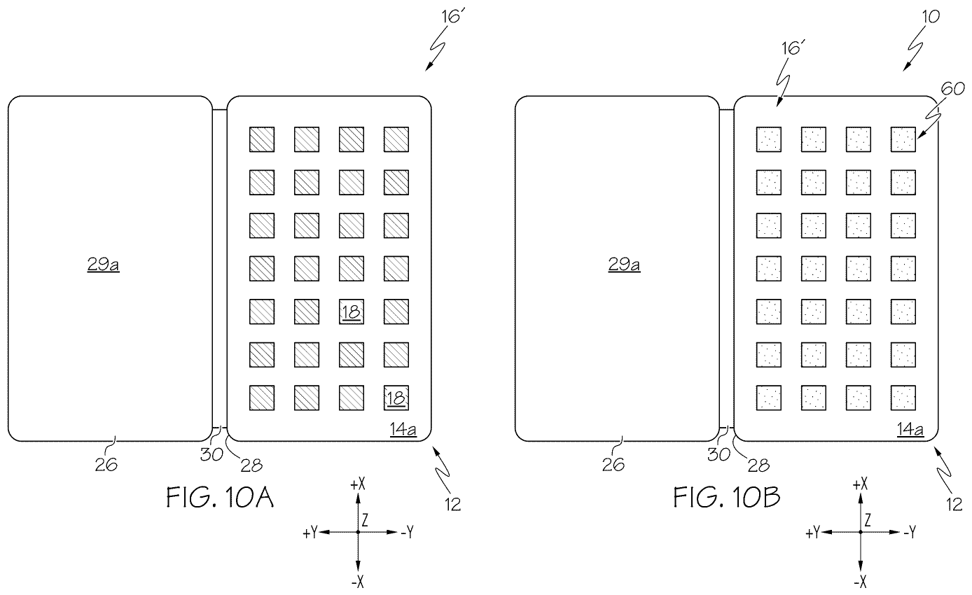

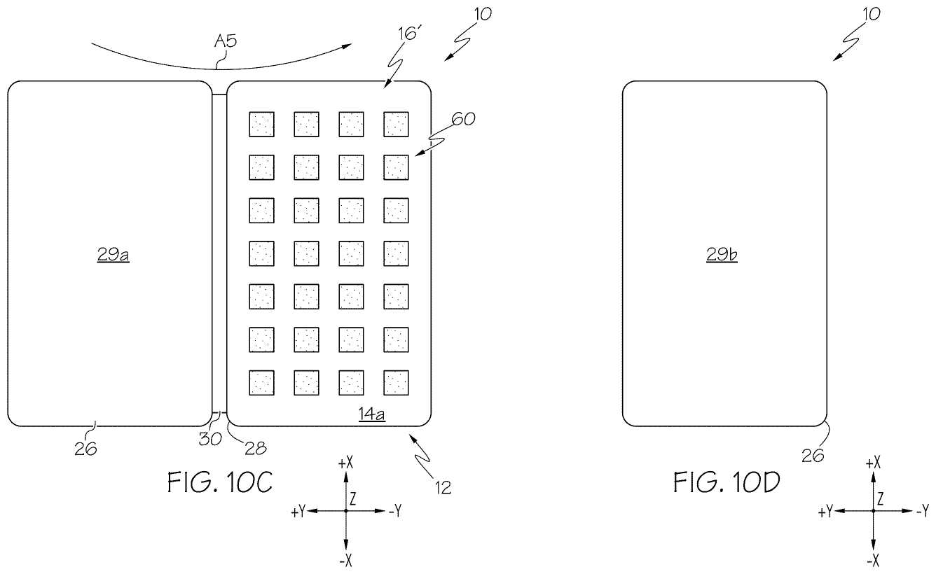

Further, the recess 16 may not be limited to a single recess, and instead may be a plurality of recesses 16′ or receiving cavities, as best depicted in the embodiment of at least FIG. 10A. Each of the plurality of recesses 16′ may be formed by chemical etching, stamping and/or machined, for example, combination thereof, and/or any other suitable process. As depicted in this embodiment, each recess of the plurality of recesses 16′ may be fabricated into the substrate 12 extending from the inner surface 14a in the vertical direction (i.e., in the +/−Z direction) towards the outer surface 14b through a portion of the thickness. Further, in the depicted embodiment, each recess of the plurality of recesses 16′ may be spaced apart in a uniform arrangement. In other embodiments, the plurality of recesses 16′ may be in an irregular arrangement with varying spacing, varying number of recesses, and/or the like. Further, each recess of the plurality of recesses 16′ is depicted as generally square in shape. This is non-limiting, each of the plurality of recesses 16′ may be any shape, including without limitation, rectangular, elliptical, circular hexagonal, octagonal, combinations thereof, and/or the like. Each of the plurality of recesses 16′ are configured to receive at least a portion of the plurality of graphite members 22, as discussed in greater detail herein.

The substrate 12 may be made of any suitable metal or alloy. Copper and aluminum may be used as the substrate, as non-limiting examples.

The at least one power electronic device 20 may be coupled or otherwise bonded to the outer surface 14b of the substrate 12 using known methods. For example, the at least one power electronic device 20 may be coupled to the outer surface 14b via a plurality of bonding techniques, such as silver sintering, soldering, copper sintering, die bonding, wire bonding, flip chip bonding, soldering, epoxy, combinations thereof, and/or the like. As such, the position of the at least one power electronic device 20 may be customized anywhere along the outer surface 14b of the substrate 12.

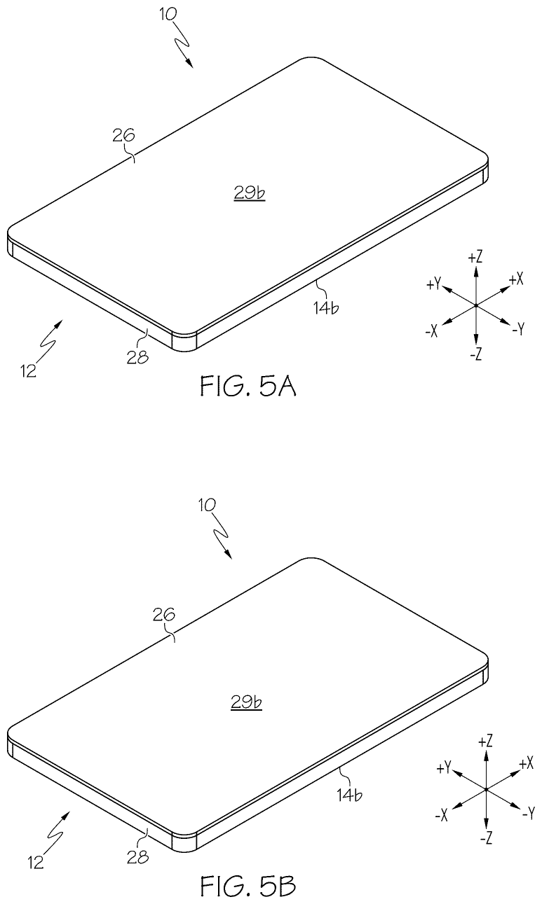

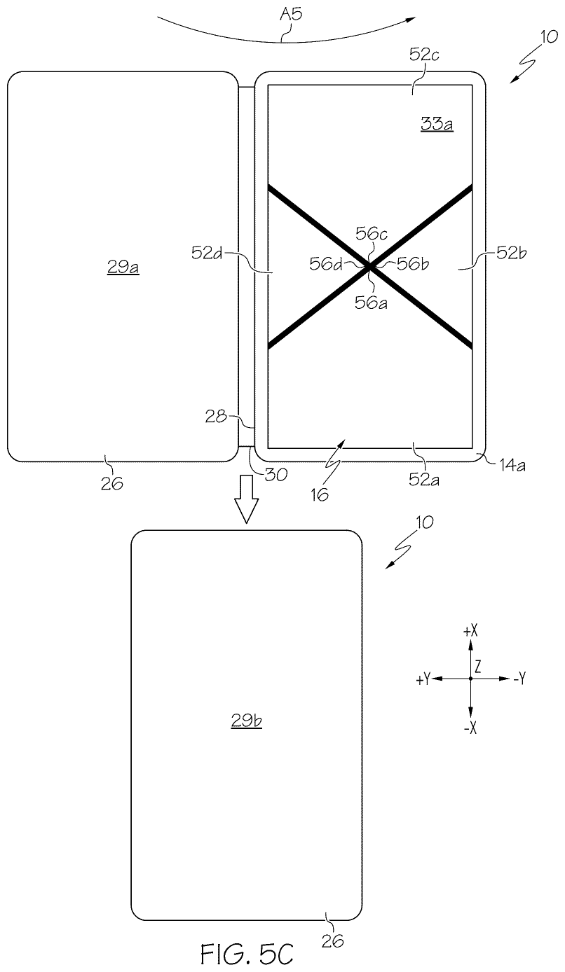

Referring back to FIGS. 2-5C, in some embodiments, the example heat spreader assembly 10 includes a cover member 26. The cover member 26 has an interior cover surface 29a spaced apart from an exterior cover surface 29b to define a thickness there between. In some embodiments, the cover member 26 may be sintered to a sidewall 28 of the substrate 12 to define a living hinge 30. In this embodiment, the cover member 26 may be configured to be movable between an access state, where the interior cover surface 29a of the cover member 26 is spaced apart from the inner surface 14a of the substrate 12 via the living hinge 30 such that access is permitted to recess 16, as best depicted in FIGS. 5C and 10A-10C, and a closed state where the interior cover surface 29a of the cover member 26 abuts the inner surface 14a of the substrate 12 via the living hinge 30 such that access is inhibited to the recess 16 by the cover member 26 by covering the recess 16 illustrated by arrow A5, in FIGS. 5C and 10C and in the closed state best depicted in FIGS. 5C and 10D. In embodiments, the cover member 26 is a monolithic structure that is fabricated with the substrate 12 to be a single piece with the substrate 12 that includes the living hinge 30 such that the cover member 26 may be configured to be movable between the access state and the closed state, as discussed above.

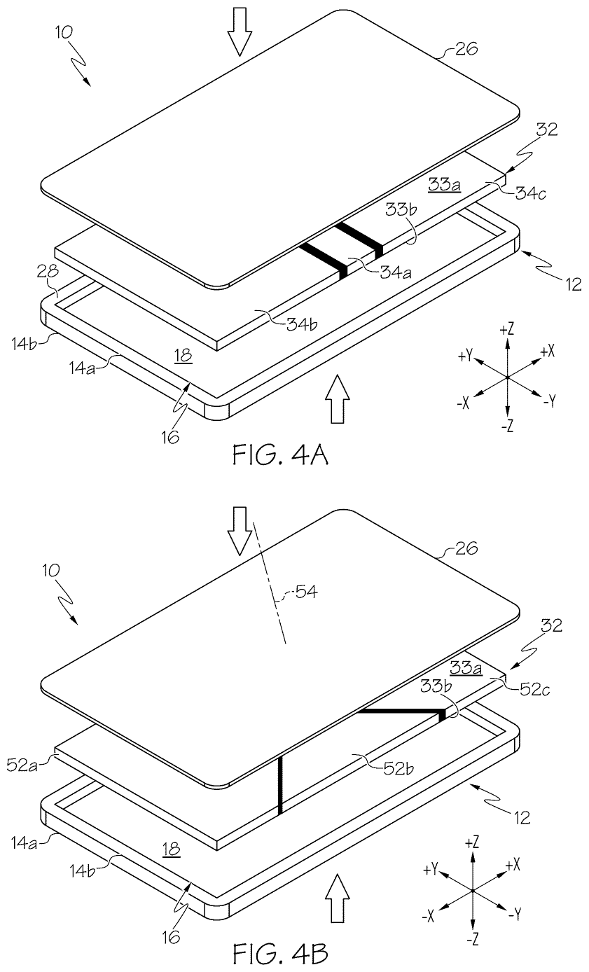

In other embodiments, the cover member 26 may be a separate member that is independent from the substrate 12 and that is configured to be bonded (e.g., either directly or with a bonding layer) to the inner surface 14a of the substrate 12 to cover or encapsulate the recess 16 such that the cover member 26 is in the closed state, as best illustrated in FIGS. 4A-4B and 5A-5B. Example bonding techniques include, without limitation, silver sintering, soldering, copper sintering, welding, epoxy, adhesive, and/or the like. As such, in this embodiment, there is not a living hinge 30.

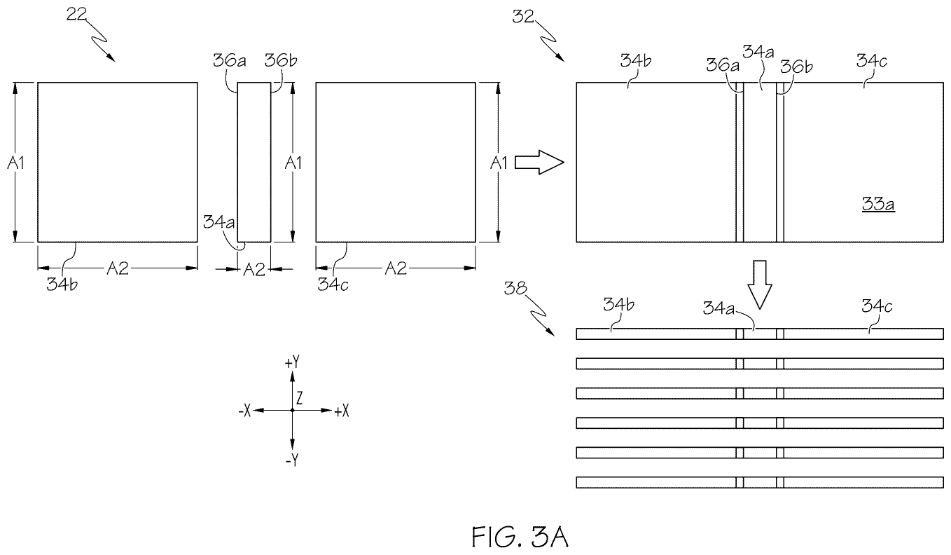

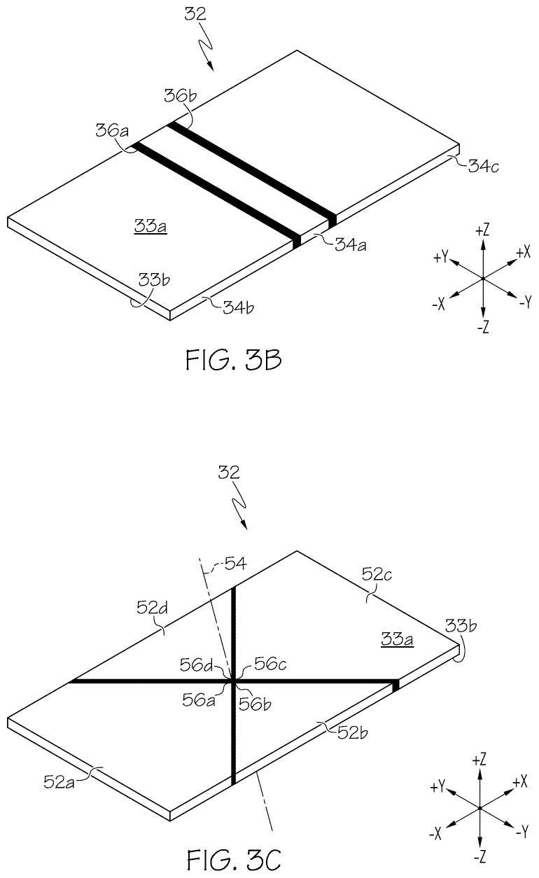

Now referring to FIGS. 3A-3C 4A-4B, 5A-5C, and 6A, in the depicted embodiment, the plurality of graphite members 22 are bonded into a single-layer graphite plate 32 that includes the interior surface 33a and the exterior surface 33b. The single-layer graphite plate 32 is positioned within the recess 16 of the substrate 12 to form the example heat spreader assembly 10. In one embodiment, as best depicted in FIGS. 3A-3B, and 4A, the single-layer graphite plate 32 includes three or more adjacent graphite members that are arranged in a side-center-side graphite configuration such that a center graphite member 34a and two side graphite members 34b, 34c of the plurality of graphite members 22 contact with the center graphite member 34a along a left parallel edge 36a and a right parallel edge 36b of the center graphite member 34a, respectively, to define a planar plate arrangement. That is, the center graphite member 34a has a same length with the two side graphite members 34b, 34c along a first axis, depicted by arrow A1 in FIG. 3A in the longitudinal direction (i.e., in the +/−Y direction), and has different length compared with the two side graphite members 34b, 34c along a second axis, depicted by arrow A2 in FIG. 3A in the lateral direction (i.e., in the +/−X direction).

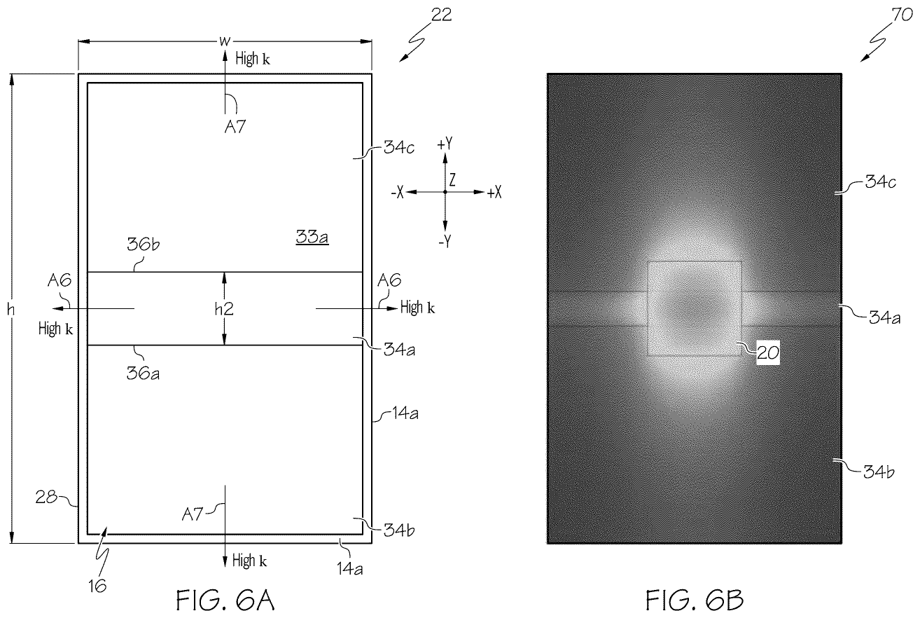

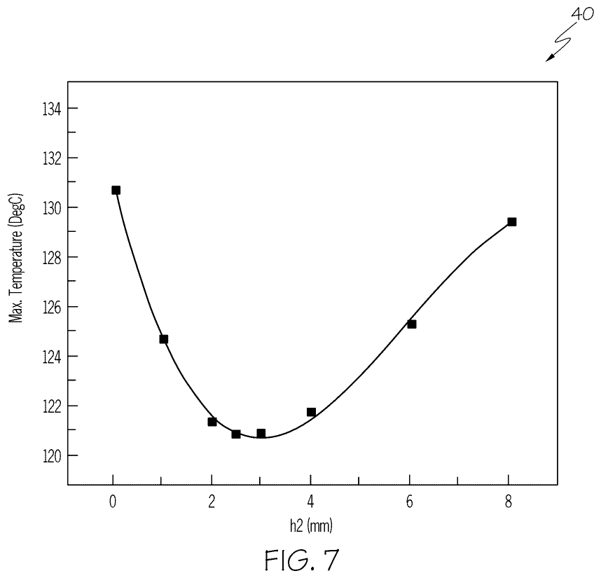

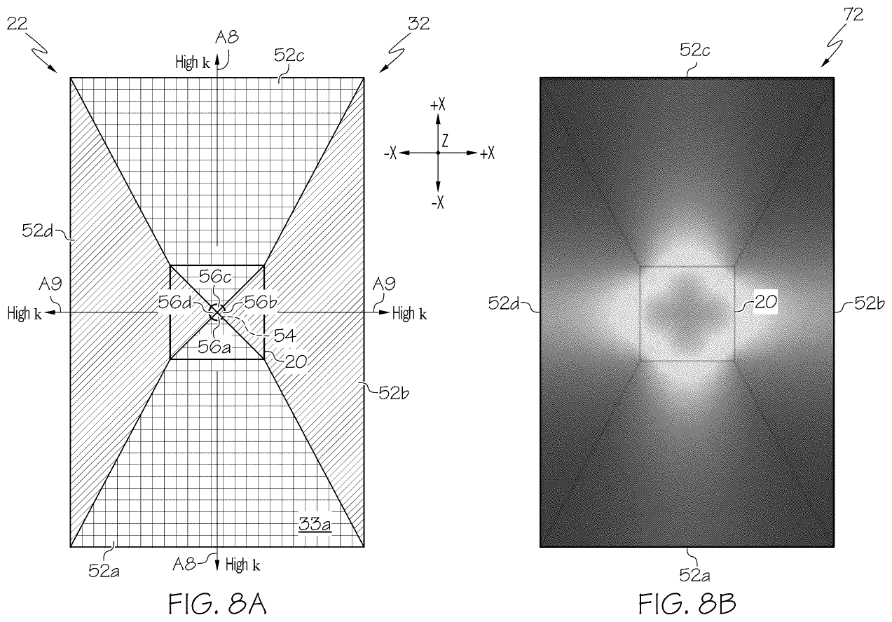

In this arrangement, each of the plurality of graphite members 22 are arranged such that one of the plurality of graphite members 22 has a high thermal conductivity in the lateral direction (i.e., in the +/−X direction) and a low thermal conductivity in the longitudinal direction (e.g., in the +/−Y direction). In this arrangement, at least two of the plurality of graphite members 22 each have the high thermal conductivity in the longitudinal direction (i.e., in the +/−Y direction) and the low thermal conductivity in the lateral direction (i.e., in the +/−X direction). That is, in more detail, in this embodiment, the center graphite member 34a has the high thermal conductivity (high k) in the lateral direction (i.e., in the +/−X direction), depicted best by arrows A6 in FIG. 6A, and the low thermal conductivity (low k) in the longitudinal direction (i.e., in the +/−Y direction). The two side graphite members 34b, 34c each have a high thermal conductivity (high k) in the longitudinal direction (i.e., in the +/−Y direction), depicted best by arrows A7 in FIG. 6A, and the low thermal conductivity (low k) in the lateral direction (i.e., in the +/−X direction). Accordingly, using different graphite members with varying thermal conductivities allows for customized heat spreading to optimize a heat transfer of the substrate 12, as discussed in greater detail herein.

As described herein, high thermal conductivity (high k) generally means that the rate of heat transfer through material is approximately ~1500 W/m*K (watts per meter kelvin) and low thermal conductivity (low k) generally means that the rate of heat transfer through material is approximately ~10 W/m*K (watts per meter kelvin).

As such, the single-layer graphite plate 32 depicted in the embodiment of FIGS. 3A-3C 4A-4B, 5A-5C, and 6A is provided to encourage heat spreading both across the heat spreader assembly 10 as well as toward a cooling device. It should be appreciated that a crystalline structure of graphite provides each of the plurality of graphite members 22 with high thermal conductivity, making it useful to conduct heat flux toward the cooling device. However, graphite does not have an isothermal profile. Rather, graphite has an anisothermal profile with high conductivity along two axes and low thermal conductivity in a third axis. To account for the anisothermal profile of graphite, each of the plurality of graphite members 22 has a high thermal conductivity across two axes (e.g., the side graphite members 34b, 34c) that differs from the two axes of another graphite of the plurality of graphite members 22 (e.g., center graphite member 34a) to provide a balanced thermal conductivity along each of the three axes of the single-layer graphite plate 32. In embodiments, the single-layer graphite plate 32 may include three or more adjacent graphite members (e.g., the left side graphite member 34b, the right side graphite member 34c, and the center graphite member 34a) having high thermal conductivity along the vertical direction (i.e., in the +Z direction). In other words, as described and shown herein, each of the plurality of graphite members 22 have a high thermal conductivity (high k) in the vertical direction (i.e., in the +/−Z direction) meaning that each of the center graphite member 34a and the two side graphite members 34b, 34c have a high thermal conductivity (high k) in the vertical direction (i.e., in the +/−Z direction).

In this arrangement, each of the center graphite member 34a and the two side graphite members 34b, 34c have an equal thickness that may be equal to or greater than 10.00 mm. This is non-limiting and each of the center graphite member 34a and the two side graphite members 34b, 34c may have a thickness less than 10.00 mm such as 7.00 mm, 5.00 mm and/or the like. In other embodiments, each of the each of the center graphite member 34a and the two side graphite members 34b, 34c may have a varying thickness.

In the depicted embodiment, the single-layer graphite plate 32 may have a width (w), such as, without limitation, 25 mm, and a height (h), such as 40 mm, that is formed by bonding the left-side graphite member 34b to the center graphite member 34a along the left parallel edge 36a of the center graphite member 34a and bonding the right-side graphite member 34c to the center graphite member 34a along the right parallel edge 36b of the center graphite member 34a, as best depicted in FIG. 6A. The center graphite member 34a may have a width, depicted by arrow A2 that is smaller than the width of the each of the side graphite members 34b, 34c as best depicted in FIG. 3A. The center graphite member 34a, the left side graphite member 34b and the right side graphite member 34c may have a same length, depicted by arrow A1 in FIG. 3A, such that the center graphite member 34a, the left side graphite member 34b and the right side graphite member 34c define the same height of h as the height of the single-layer graphite plate 32, as best depicted in FIG. 6A.

The left-side graphite member 34b is bonded the center graphite member 34a and the right-side graphite member 34c is bonded to the center graphite member 34a using high temperature brazing techniques. As described herein, high temperature brazing means a joining process that takes place in a vacuum furnace or controlled atmosphere at above 900° C. to create high-strength bonds with good corrosion and oxidation resistance joining. As such, the sectioned plurality of graphite members (e.g., the center graphite member 34a and the two side graphite members 34b, 34c) are joined together via the high temperature brazing to form the single-layer graphite plate 32.

Following the joining of the plurality of graphite members to form the single-layer graphite plate 32, in the embodiments of FIG. 3A, the single-layer graphite plate 32 is then optionally or selectively sliced in the lateral direction (i.e., in the +/−X direction) to form a plurality of graphite elongated members 38.

It should be appreciated that the slicing of the single-layer graphite plate 32 into the plurality of graphite elongated members 38 may be by any known processes, including without limitation, diamond saw cutting. Each of the plurality of graphite elongated members 38 are then bonded into the recess 16 of the substrate 12 to be bonded to the recess interior surface 18. As such, because the plurality of graphite elongated members 38 have varying thermal conductively along the lateral direction (e.g., in the +/−X direction), the placement of the plurality of graphite elongated members 38 provides for a customized and optimized heat transfer to desirable locations within and/or out of the substrate 12.

That is, because the at least one power electronic device 20 may be configured to be positioned to abut, or be adjacent to the center portion area of at least some of the plurality of graphite elongated members 38, and as best depicted in FIG. 6B by the color map 70, the heat generated by the at least one power electronic device 20 may be directed or guided to desirable positions or locations away from the at least one power electronic device 20 within the substrate 12 to a more desirable location, as described in greater detail herein.

Now referring to FIG. 7, which graphically depicts the influence of the height of the center graphite member 34a of the single-layer graphite plate 32 of FIG. 6A. In some embodiments, as illustrated in FIG. 7, the height (h₂) of the center graphite member 34a of the single-layer graphite plate 32 may be different than the height of the side graphite members 34b, 34c, as best illustrated in FIG. 6A. As illustrated in plotting 40, the maximum temperature of the heat spreader assembly 10 may be a function of the height (h₂) of the center graphite member 34a. For example, the lowest maximum temperature of the heat spreader assembly 10 may be 120.9° C., which may be achieved with the height (h₂) of the center graphite member 34a around 3.0 mm with the height (h) of the single-layer graphite plate 32 around 40.0 mm. In embodiments, the height (h₂) of the center graphite member 34a along the lateral direction (e.g., in the +/−X direction) may be less than or equal to 1%, 2.5%, 5%, 7.5%, 10%, 12.5%, 15%, 17.5%, 20%, 22.5%, 25%, 27.5%, 30%, 35%, 40%, 45%, 50%, or any number between 1% and 50% of the height (h) of the single-layer graphite plate 32 along the lateral direction (e.g., in the +/−X direction). In embodiments, the height (A₂) of the center graphite member 34a along the lateral direction (e.g., in the +/−X direction) is greater than or equal to 1%, 2.5%, 5%, 7.5%, 10%, 12.5%, 15%, 17.5%, 20%, 22.5%, 25%, 27.5%, 30%, 35%, 40%, 45%, 50%, or any number between 1% and 50% of the height (h) of the single-layer graphite plate 32 along the lateral direction (e.g., in the +/−X direction). In embodiments, the height (h₂) of the center graphite member 34a along the x-axis are between 1% and 50%, 5% and 45%, 10% and 40%, 15% and 35%, 20 % and 30%, or any range from 1% and 50% of the height (h) of the single-layer graphite plate 32 along the lateral direction (e.g., in the +/−X direction).

Although not shown, it should be appreciated that the heat spreader assembly 10 may include more than one of the single-layer graphite plate 32. For example, the heat spreader assembly 10 may include two, three, four, or more than four of the single-layer graphite plates 32 positioned in any suitable arrangement such as, for example, one or more lower graphite layers and one or more upper graphite layers provided on the lower graphite layers and rotated 90 degrees relative to the one or more lower graphite layers such that the high thermal conductivity (high k) and the low thermal conductivity (low k) directions of the lower graphite layers differs from the high thermal conductivity (high k) and the low thermal conductivity (low k) directions of the upper graphite layers. As another non-limiting example, the graphite layers may alternate such that graphite layers arranged in a first orientation are interposed between graphite layers arranged in a second orientation different from the first orientation, i.e., 90 degrees offset to directional change or alternate the high thermal conductivity (high k) and the low thermal conductivity (low k) directions.

Now referring to FIGS. 3C, 4B, 5C, 8A, and 9A, in another embodiment, the single-layer graphite plate 32 is formed from four or more adjacent graphite members that are bonded to be arranged as a first portion 52a, a second portion 52b, a third portion 52c, and a fourth portion 52d. As such, similar to the above described embodiment, each of the portions 52a, 52b, 52c, 52d are bonded together to form the single-layer graphite plate 32 using high temperature brazing techniques. The recess 16 of the substrate 12 includes an imaginary center point 54 that is centrally positioned within the recess 16. Each portion 52a, 52b, 52c, 52d has an apex 56a, 56b, 56c, 56d, respectively, that contacts with the center point 54 when the single-layer graphite plate 32 is positioned within the recess 16 of the substrate 12. In the depicted embodiment, each of the portions 52a, 52b, 52c, 52d are triangular in shape. For example, and without limitation, one or all of the portions 52a, 52b, 52c, 52d may be equilateral triangle, isosceles triangle, scalene triangle, an acute triangle, right triangle, obtuse triangle, combinations thereof (e.g., having both acute and obtuse angles), and/or the like. This is non-limiting and each of the portions 52a, 52b, 52c, 52d may be any shape, such as without limitation, octagonal, hexagonal, pentagonal, and/or the like.

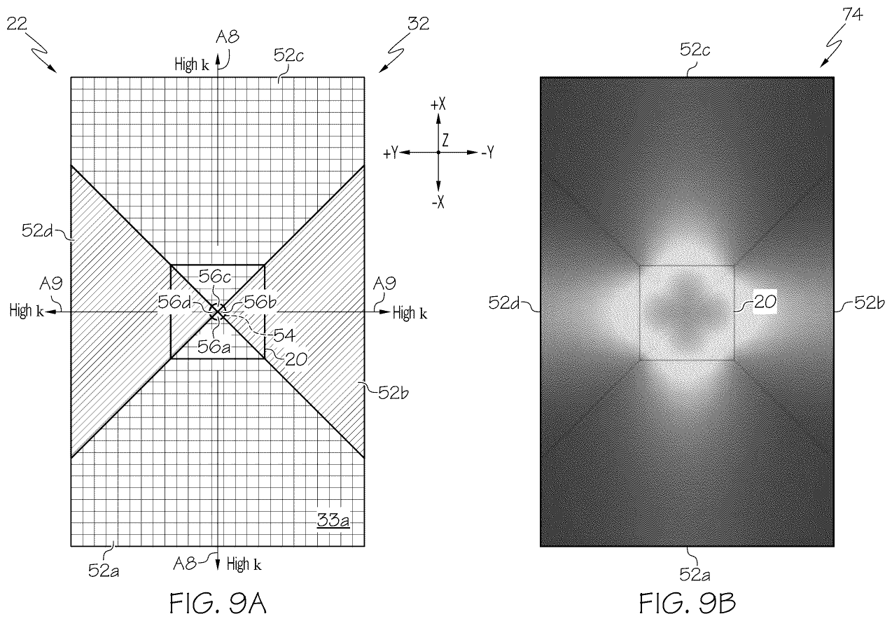

In the depicted embodiment, the first portion 52a and the third portion 52c each have the high thermal conductivity (high k) in the longitudinal direction (i.e., in the +/−Y direction), depicted best by arrows A8 in FIGS. 8A and 9A, and the low thermal conductivity (low k) in the lateral direction (i.e., in the +/−X direction). Further, the second portion 52b and the fourth portion 52d each have the high thermal conductivity (high k) in the lateral direction (i.e., in the +/−X direction), depicted best by arrows A9 in FIGS. 8A and 9A, and the low thermal conductivity (low k) in the longitudinal direction (i.e., in the +/−Y direction). Further still, all four portions 52a, 52b, 52c, 52d each have the high thermal conductivity (high k) in the vertical direction (i.e., in the +/−Z direction). Similar to above, the single-layer graphite plate 32 is a planar plate arrangement that utilizes different sectional graphite members with varying thermal conductivities for customized heat spreading to optimize the heat transfer of the substrate 12, as discussed in greater detail herein.

Although not shown, it should be appreciated that the heat spreader assembly 10 may include more than one of the single-layer graphite plate 32 formed from the portions 52a, 52b, 52c, 52d. For example, the heat spreader assembly 10 may include two, three, four, or more than four of the single-layer graphite plate 32 formed from the portions 52a, 52b, 52c, 52d and positioned in any suitable arrangement such as, for example, one or more lower graphite layers and one or more upper graphite layers provided on the lower graphite layers and rotated 90 degrees relative to the one or more lower graphite layers such that the high thermal conductivity (high k) and the low thermal conductivity (low k) directions of the lower graphite layers differs from the high thermal conductivity (high k) and the low thermal conductivity (low k) directions of the upper graphite layers. As another non-limiting example, the graphite layers may alternate such that graphite layers arranged in a first orientation are interposed between graphite layers arranged in a second orientation different from the first orientation, i.e., 90 degrees offset to directional change or alternate the high thermal conductivity (high k) and the low thermal conductivity (low k) directions.

Further, in other embodiments, following the joining of the plurality of graphite members 22 to form the single-layer graphite plate 32, the single-layer graphite plate 32 is optionally or selectively sliced in the lateral direction (i.e., in the +/−X direction) to form the plurality of graphite elongated members 38 in a similar manner described above and is bonded to the recess in a similar manner described above. As such, each of the portions 52a, 52b, 52c, 52d have varying thermal conductively, the placement of the plurality of graphite elongated members 38 provides for a customized and optimized heat transfer to desirable locations within and/or out of the substrate 12. That is, because the at least one power electronic device 20 may be configured to be positioned to abut, or be adjacent to the center point 54 of the recess 16 and abut, or positioned adjacent to the apex 56a, 56b, 56c, 56d of the portions 52a, 52b, 52c, 52d, respectively, and as best depicted in FIG. 8B by the color map 72 and in FIG. 9B by the color map 74, the heat generated by the at least one power electronic device 20 may be directed or guided to desirable positions or locations away from the at least one power electronics device 20.

Now referring to FIGS. 5A-5C, and 10D, the substrate 12 including the cover member 26 and the single layer graphite plate 32 bonded to the interior surface 18 of the recess 16 is baked in an oven to complete the bonding process. It should be understood that those having skill in the art will understand the type of oven, the temperature and the timing to bake the substrate 12 based on several factors including the type of bonding agent used.

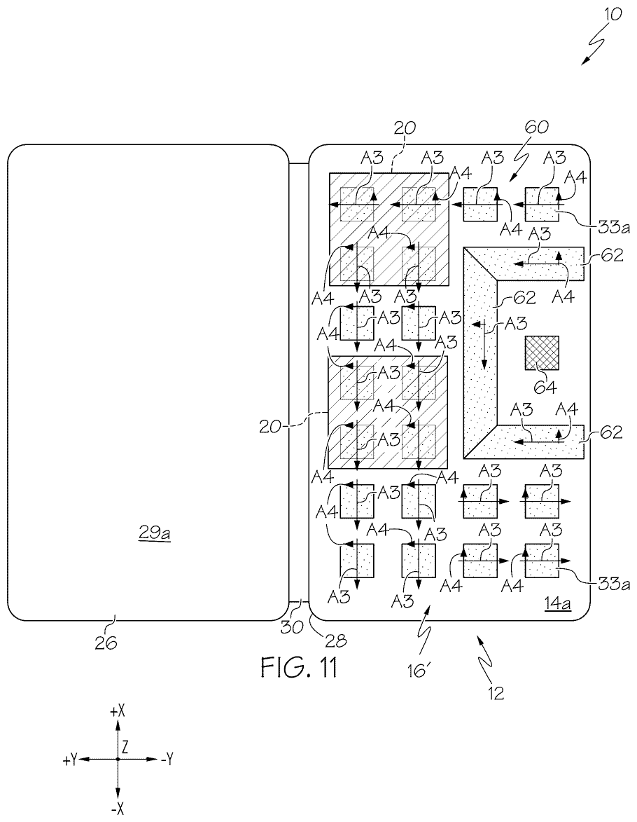

Now referring to FIGS. 10A-10D and 11, the substrate 12 includes the plurality of recesses 16′, the method further includes or continues by dividing the plurality of graphite elongated members 38 into a plurality of graphite insert members 60. Each of the plurality of graphite insert members 60 may be sized and shaped to be bonded within a corresponding one of the plurality of recesses 16′. In a non-limiting example, in the depicted embodiment, each of the plurality of plurality of graphite insert members 60 are sized and shaped in a generally square shape to correspond to the size and shape of the plurality of recesses 16′. This is non-limiting and each of the plurality of recesses 16′ and each of the plurality of graphite insert members 60 may be any shape including, without limitation, rectangular, circular, elliptical, hexagonal, triangular, octagonal, combinations thereof, and the like.

Further, in some embodiments, some of the plurality of recesses 16′ and the corresponding some of the plurality of graphite insert members 60 may be different shapes, such graphite insert members that has a rectangular with an angled edge 62, as best illustrated in FIG. 11, while the remaining the plurality of recesses 16′ and the plurality of graphite insert members 60 are a different shape, such a square, as best depicted in FIG. 11. As such, the arrangement and configuration of the plurality of recesses 16′ and each of the corresponding plurality of graphite insert members 60 are customizable to be tuned to move or direct heat as desired by the application for use.

Further, each of the plurality of graphite insert members 60 may be placed and bonded to precisely direct the heat generated from the at least one power electronic device 20 into desirable areas. That is, because each of the plurality of graphite insert members 60 has the high thermal conductivity (high k) in one direction (e.g., the lateral direction in the +/−X direction) and a low thermal conductivity (low k) in an opposing direction (e.g., the longitudinal direction in the +/−Y direction), and the high thermal conductivity (high k) in the vertical direction (i.e., in the +/−Z direction) when adding the plurality of graphite insert member 60 into a corresponding one of a plurality of recesses 16′, each of the plurality of graphite insert members 60 may be rotated or orientated to be positioned such that the high thermal conductivity (high K) direction pushes the heat into a desirable direction and the low thermal conductivity (low K) direction orientated in a perpendicular direction, as best illustrated in FIG. 11. This permits for customization of the directionality of the thermal flow of heat generated from the at least one power electronic device 20 along the substrate 12 to the cooling device.

For example, with reference to FIG. 11, the arrows indicted by A3 schematically depicted on each of the plurality of graphite insert members 60 as the high thermal conductivity (high k) in the direction indicated by the arrow A3 (e.g., the lateral direction in the +/−X direction) and the arrows indicted by A4 schematically depicted on each of the plurality of graphite insert members 60 as the low thermal conductivity (low k) in the direction indicated by the arrow A4 (e.g., the longitudinal direction in the +/−Y direction)

As such, and as illustrated best in FIG. 11, this arrangement permits for the inclusion of both high heat type of the at least one power electronic device 20 and temperature sensitive at least one power electronic device 64 where the temperature sensitive power electronic device 64 may be shielded from the heat generated by the at least one power electronic device 20 based on the arrangement of the graphite insert members that has the angled edge 62 and/or the customized thermal transfer of the plurality of graphite insert members 60, which permits for tuning of the substrate 12 based on the type of heat generated and/or sensitivity of heat by the individual power electronic device 20, 64.

Although not shown, it should be appreciated that the plurality of graphite insert members 60 may be formed by more than one of the single-layer graphite plate 32. For example, the plurality of graphite insert members 60 may include two, three, four, or more than four of the single-layer graphite plates 32 positioned in any suitable arrangement such as, for example, one or more lower graphite layers and one or more upper graphite layers provided on the lower graphite layers and rotated 90 degrees relative to the one or more lower graphite layers such that the high thermal conductivity (high k) and the low thermal conductivity (low k) directions of the lower graphite layers differs from the high thermal conductivity (high k) and the low thermal conductivity (low k) directions of the upper graphite layers. As another non-limiting example, the graphite layers may alternate such that graphite layers arranged in a first orientation are interposed between graphite layers arranged in a second orientation different from the first orientation, i.e., 90 degrees offset to directional change or alternate the high thermal conductivity (high k) and the low thermal conductivity (low k) directions.

It should now be understood that embodiments of the present disclosure are directed a customized heat spreader. The heat spreader may include a single-layer graphite layer that may include three or more graphite pieces with different directions of the high thermal conductivity that may be arranged or orientated to guide or direct heat in a customized manner thereby improving heat flux from the heat spreader and increasing heat spreading and cooling performance relative to conventional assemblies.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

It will be apparent to those skilled in the art that various modifications and variations can be made to the embodiments described herein without departing from the scope of the claimed subject matter. Thus, it is intended that the specification cover the modifications and variations of the various embodiments described herein provided such modifications and variations come within the scope of the appended claims and their equivalents.

What is claimed is:

1. A method for fabricating a substrate with graphite embedded for customized heat spreading directions, the method comprising:
bonding a plurality of graphite members having a planar orientation into a single-layer plate arrangement, the plurality of graphite members are arranged such that one of the plurality of graphite members has a high thermal conductivity in a lateral direction and a low thermal conductivity in a longitudinal direction and at least two of the plurality of graphite members each have a high thermal conductivity in the longitudinal direction and a low thermal conductivity in the lateral direction;
bonding the single layer plate arrangement into a recess; and
positioning a cover member in a closed state to enclose the single layer plate arrangement.

2. The method of claim 1, wherein the bonding of the plurality of graphite members together is under a high temperature.

3. The method of claim 1, wherein the plurality of graphite members are arranged in a side-center-side graphite piece configuration such that a center graphite member and two side graphite members of the plurality of graphite members contact with the center graphite member along two parallel edges of the center graphite member to define the single-layer plate arrangement.

4. The method of claim 3, wherein the center graphite member has a same length with the two side graphite members along a first axis, and has different length compared with the two side graphite members along a second axis.

5. The method of claim 3, wherein the center graphite member has the high thermal conductivity in the lateral direction and the low thermal conductivity in the longitudinal (Y) direction and the two side graphite members each have the high thermal conductivity in the longitudinal direction and the low thermal conductivity in the lateral (X) direction.

6. The method of claim 1, wherein the plurality of graphite members are arranged in a first portion, a second portion, a third portion and a fourth portion to define the single-layer plate arrangement, the recess having a center point, an apex of each of the first portion, the second portion, the third portion and the fourth portion contacting the center point.

7. The method of claim 6, wherein the first portion and the third portion each have the high thermal conductivity in the longitudinal direction and the low thermal conductivity in the lateral direction.

8. The method of claim 7, wherein the second portion and the fourth portion each have the high thermal conductivity in the lateral direction and the low thermal conductivity in the longitudinal direction.

9. The method of claim 8, wherein the first portion, the second portion, the third portion and the fourth portion each have the high thermal conductivity in a vertical direction.

10. The method of claim 1, wherein each of the plurality of graphite members have a thickness of at least 10 millimeters.

11. The method of claim 1, wherein the cover member has a living hinge to be movable between an access state where access is permitted to the recess and a closed state where access is inhibit to the recess by the cover member.

12. A method for fabricating a substrate with graphite embedded for customized heat spreading directions, the method comprising:
bonding a plurality of graphite members to form a single-layer plate arrangement, the plurality of graphite members are arranged such that one of the plurality of graphite members has a high thermal conductivity in a first direction and a low thermal conductivity in a second direction, the second direction different from the first direction and at least two of the plurality of graphite members each have the high thermal conductivity in the first direction and the low thermal conductivity in the second direction;
slicing the single-layer plate arrangement into a plurality of graphite elongated members;
dividing the plurality of graphite elongated members into a plurality of graphite insert members; and
bonding the plurality of graphite insert members into a corresponding one of a plurality of recesses of the substrate.

13. The method of claim 12, wherein a density and an orientation of the high thermal conductivity of each of the plurality of graphite insert members is configured to be tuned to guide a heat from a heat source to a desirable location.

14. The method of claim 13, wherein the high thermal conductivity of each of the plurality of graphite insert members tuned to the first direction is configured to guide the heat from the heat source to the desirable location and push the heat away from an undesirable location to generate a low heat spreading area for other devices.

15. The method of claim 14, wherein the high thermal conductivity of each of the plurality of graphite insert members tuned to the first direction is further configured to eliminate heat interference between the heat source and the other devices.

16. The method of claim 12, wherein each of the plurality of graphite insert members has a high thermal conductivity in a third direction, the third direction being perpendicular to a substrate surface of each of plurality of graphite insert members.

17. A method for fabricating a substrate with graphite embedded for customized heat spreading directions, the method comprising:
bonding a plurality of graphite members into single-layer plate arrangement, the plurality of graphite members are arranged such that one of the plurality of graphite members has a high thermal conductivity in a first direction and a low thermal conductivity in a second direction, the second direction different from the first direction and at least two of the plurality of graphite members each have the high thermal conductivity in the first direction and the low thermal conductivity in the second direction;
slicing the single-layer plate arrangement into a plurality of graphite elongated members;
adding the plurality of graphite elongated members into a recess; and
positioning a cover member to enclose the plurality of graphite elongated members.

18. The method of claim 17, wherein:
the plurality of graphite members in the single-layer plate arrangement are arranged in a side-center-side graphite piece configuration such that a center graphite member and two side graphite members of the plurality of graphite members contact with the center graphite member along two parallel edges of the center graphite member to define the single-layer plate arrangement, and
the center graphite member has a same length with the two side graphite members along a first axis, and has different length compared with the two side graphite members along a second axis.

19. The method of claim 18, wherein the center graphite member has the high thermal conductivity in the first direction and the low thermal conductivity in the second direction and the two side graphite members each have the high thermal conductivity in the second direction and the low thermal conductivity in the first direction.

20. The method of claim 17, wherein:
the plurality of graphite members in the single-layer plate arrangement are arranged in a first portion, a second portion, a third portion and a fourth portion to define, the recess having a center point, an apex of each of the first portion, the second portion, the third portion and the fourth portion contacting the center point, and
the first portion and the third portion each have the high thermal conductivity in the second direction and the low thermal conductivity in the first direction, the second portion and the fourth portion each have the high thermal conductivity in the first direction and the low thermal conductivity in the second direction, and each of the first portion, the second portion, the third portion and the fourth portion have the high thermal conductivity in a third direction.
